(19) United States
(12) Patent Application Publication
(10) Pub. No.: US 2025/0380438 A1
(43) Pub. Date: Dec. 11, 2025

(54) SEMICONDUCTOR DEVICE

(71) Applicant: Mitsubishi Electric Corporation, Tokyo (JP)

(72) Inventors: Kenji SUZUKI, Tokyo (JP); Seiya NAKANO, Tokyo (JP); Akira KIYOI, Tokyo (JP)

(73) Assignee: Mitsubishi Electric Corporation, Tokyo (JP)

(21) Appl. No.: 19/069,143

(22) Filed: Mar. 3, 2025

(30) Foreign Application Priority Data
Jun. 7, 2024 (JP) 2024-093159

(51) Int. Cl. H10D 12/00; H10D 12/01; H10D 62/10; H10D 62/53; H10D 62/60; H10D 62/83; H10D 62/832; H10D 62/85

(52) U.S. Cl. CPC H10D 12/481; H10D 62/102; H10D 62/53; H10D 62/60; H10D 62/8303; H10D 62/8325; H10D 62/8503; H10D 12/038

(57) ABSTRACT

A semiconductor device includes a semiconductor substrate having a principal surface and a rear surface opposite to the principal surface, a main electrode formed on the principal surface of the semiconductor substrate, a gate electrode formed in the principal surface side of the semiconductor substrate, and a rear surface electrode formed on the rear surface of the semiconductor substrate, wherein the semiconductor substrate includes a drift layer, a low resistance region formed in the rear surface side of the drift layer and being lower in resistance than the drift layer, a high resistance region formed in the rear surface side of the low resistance region and being higher in resistance than the drift layer, and a buffer layer formed in the rear surface side of the high resistance region and containing phosphorus, and the high resistance region is thicker than the low resistance region.

### BACKGROUND

### Field

The present disclosure relates to a semiconductor device.

### Background

JP 2016-46416 A discloses a semiconductor device which is not only high-speed and low-loss but also increased in withstand voltage and short-circuit withstand capability performance. A gate insulation film of this semiconductor device includes a first gate insulation film in contact with at least part of a P⁺ base layer and a second gate insulation film in contact with at least part of an N⁻ drift layer. The second gate insulation film has a thickness larger than a thickness of the first gate insulation film, and the second gate insulation film protrudes relative to the first gate insulation film in a direction parallel to a first principal surface of the semiconductor device. The distance from an interface between the N⁻ drift layer and the P⁺ base layer to a boundary between the first gate insulation film and the second gate insulation film is more than or equal to 2 μm and less than or equal to 5 μm.

In order to reduce inverter losses in a semiconductor device such as an IGBT, it is typically required to reduce conduction losses and switching losses. A current flows in the IGBT in the vertical direction. Therefore, in order to lower conduction losses, lowering of the resistance of an n layer that holds the withstand voltage, for example, has been addressed. In addition, optimization of a cell structure such that carriers which are electrons or holes are easily accumulated within the device during conduction has been addressed.

However, when carriers become excessive because of accumulation of excessive electrons or holes within Si so as to lower conduction losses and switching losses, the IGBT is easy to generate heat when in a short-circuit operation, which raises a problem in that the short-circuit withstand capability decreases. It is therefore preferable to optimize the structure of the semiconductor device in consideration of balance between conduction losses and breakdown strength as in JP 2016-46416 A, for example.

### SUMMARY

The present disclosure has been made to solve the problems described above and has an object to obtain a semiconductor device that can be improved in short-circuit withstand capability.

According to an aspect of the present disclosure, a semiconductor device includes a semiconductor substrate having a principal surface and a rear surface opposite to the principal surface; a main electrode formed on the principal surface of the semiconductor substrate; a gate electrode formed in the principal surface side of the semiconductor substrate; and a rear surface electrode formed on the rear surface of the semiconductor substrate, wherein the semiconductor substrate includes a drift layer, a low resistance region formed in the rear surface side of the drift layer and being lower in resistance than the drift layer, a high resistance region formed in the rear surface side of the low resistance region and being higher in resistance than the drift layer, and a buffer layer formed in the rear surface side of the high resistance region and containing phosphorus, and the high resistance region is thicker than the low resistance region.

Other and further objects, features and advantages of the disclosure will appear more fully from the following description.

### BRIEF DESCRIPTION OF DRAWINGS

FIG. 1 is a cross-sectional view of a semiconductor device according to a first embodiment.

FIGS. 2A to 2M are diagrams describing a method for manufacturing the semiconductor device according to the first embodiment.

FIG. 3 is a cross-sectional view of a semiconductor device according to a comparative example.

FIG. 4 is a diagram showing a relationship between distance from the rear surface of the semiconductor substrate and resistivity in the semiconductor device according to the first embodiment.

FIG. 5 is a diagram showing a relationship between distance from the rear surface of the semiconductor substrate and carrier concentration in the semiconductor device according to the first embodiment.

FIG. 6 is a diagram showing a relationship between proton peak concentration and short-circuit duration.

FIG. 7 is a diagram showing a relationship between proton peak concentration and leakage current.

FIG. 8 is a diagram showing a DLTS spectrum of electron traps obtained by proton implantation in the present embodiment.

FIG. 9 is a diagram showing a DLTS spectrum of hole traps obtained by proton implantation in the present embodiment.

FIG. 10 is a diagram showing an Arrhenius plot of electron traps obtained by proton implantation in the present embodiment.

FIG. 11 is a diagram showing an Arrhenius plot of hole traps obtained by proton implantation in the present embodiment.

### DESCRIPTION OF EMBODIMENTS

A semiconductor device according to the embodiment will be described with reference to the accompanying drawings. Components identical or corresponding to each other are indicated by the same reference characters, and repeated description of them is avoided in some cases.

### First Embodiment

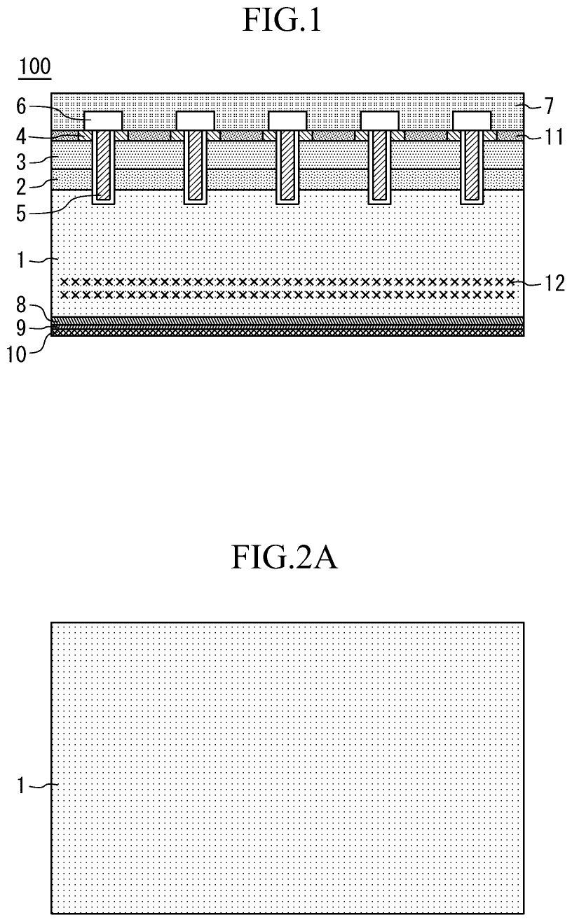

FIG. 1 is a cross-sectional view of a semiconductor device 100 according to a first embodiment. FIG. 1 shows a structure of an essential part of the semiconductor device 100. The semiconductor device 100 is an insulated gate bipolar transistor (IGBT), for example. The semiconductor device 100 includes an n-type semiconductor substrate having a principal surface and a rear surface opposite to the principal surface. In FIG. 1, components from an emitter layer 4 and a contact layer 11 positioned in the principal surface side to a collector layer 9 positioned in the rear surface side correspond to a semiconductor substrate.

The semiconductor substrate has an n-type drift layer 1. A p-type base layer 3 is provided in the principal surface side of the drift layer. The base layer 3 has a peak concentration of approximately 8.0×10¹⁶ to 5.0×10¹⁷/cm³ such that a threshold voltage Vth of the gate when a current starts flowing from the collector to the emitter is about 6 V. An n⁺-type emitter layer 4 higher in impurity concentration than the drift layer 1 and a p⁺-type contact layer 11 higher in impurity concentration than the base layer 3 are provided in the principal surface side of the base layer 3.

An n-type career stored (CS) layer 2 is provided in the rear surface side of the base layer 3. The CS layer 2 is provided for lowering conduction losses. The CS layer 2 is not essential for operation of the semiconductor device 100 of the present embodiment and may be omitted.

Trenches extending through the emitter layer 4, the base layer 3, and the CS layer 2 to reach the drift layer 1 are formed in the principal surface side of the semiconductor substrate. Gate electrodes 5 are provided in the trenches with an insulation film interposed therebetween. That is, the gate electrodes 5 are formed in the principal surface side of the semiconductor substrate. The reason that the trenches are deeper than the CS layer 2 is to stabilize a collector-emitter withstand voltage. An emitter electrode 7 which is a main electrode is formed on the principal surface of the semiconductor substrate and an upper surface of an interlayer insulation film 6.

A crystal defect region 12 is formed in the rear surface side of the drift layer 1. As will be described later, a low resistance region 22 lower in resistance than the drift layer 1 is formed in the rear surface side of the drift layer 1, and a high resistance region 21 higher in resistance than the drift layer 1 is formed in the rear surface side of the low resistance region 22, by the crystal defect region 12. The high resistance region 21 and the low resistance region 22 are provided in the rear surface side with respect to the center in a depth direction of the drift layer 1. A low concentration buffer region 23 which will be described later is further formed in the rear surface side of the high resistance region 21. A buffer layer 8 containing phosphorus is provided in the rear surface side of the high resistance region 21. A collector layer 9 is provided in the rear surface side of the buffer layer 8. A collector electrode 10 which is a rear surface electrode is formed on the rear surface of the semiconductor substrate.

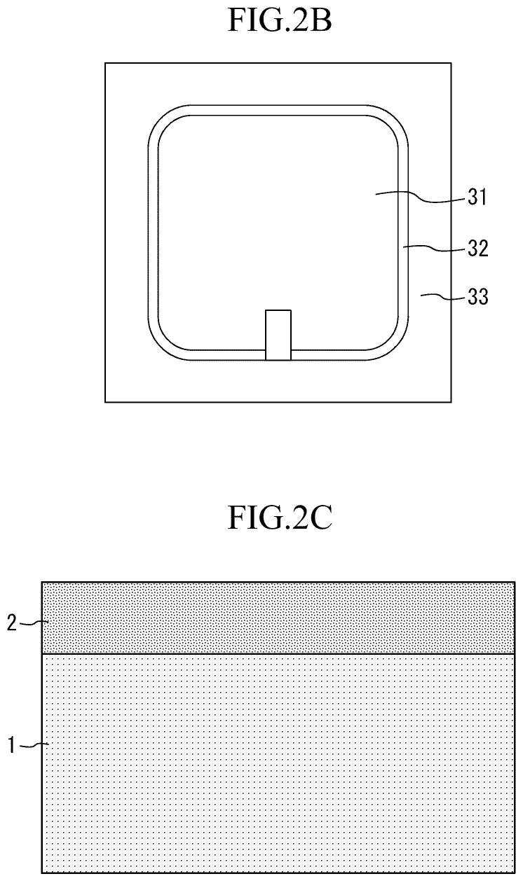

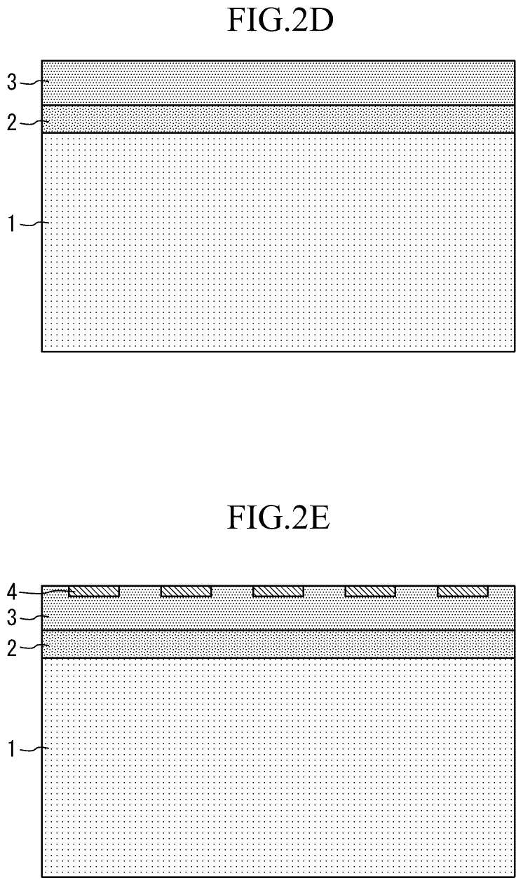

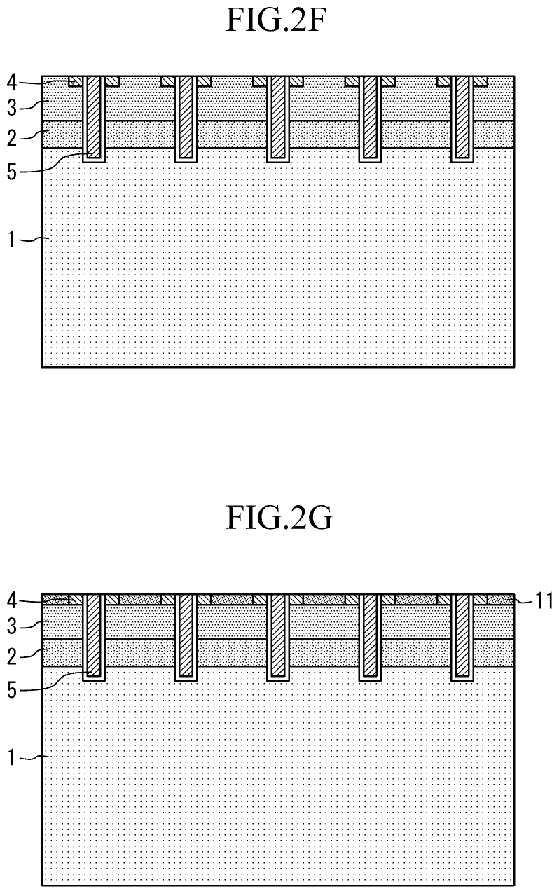

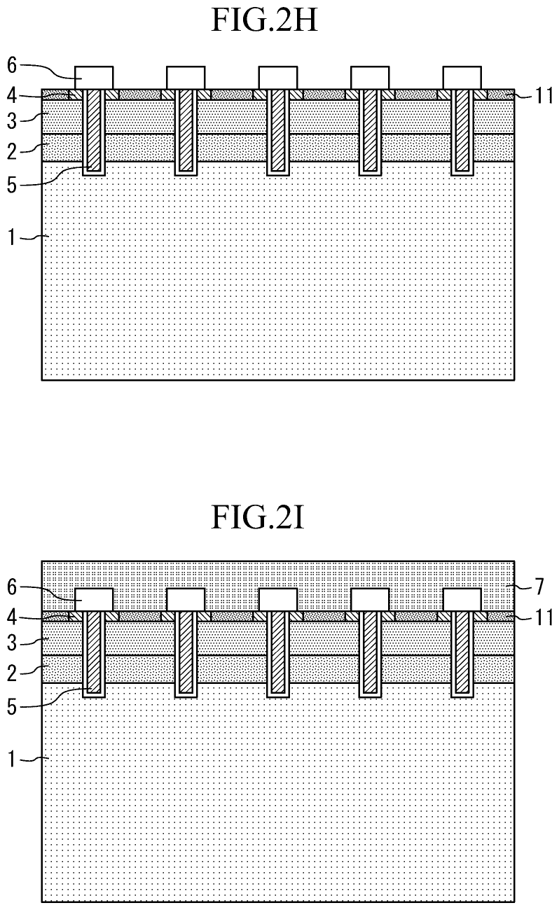

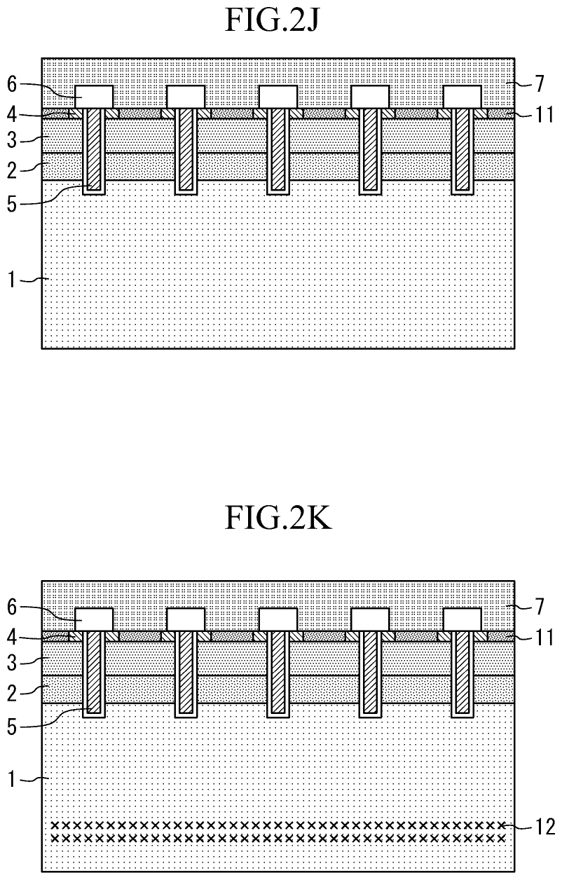

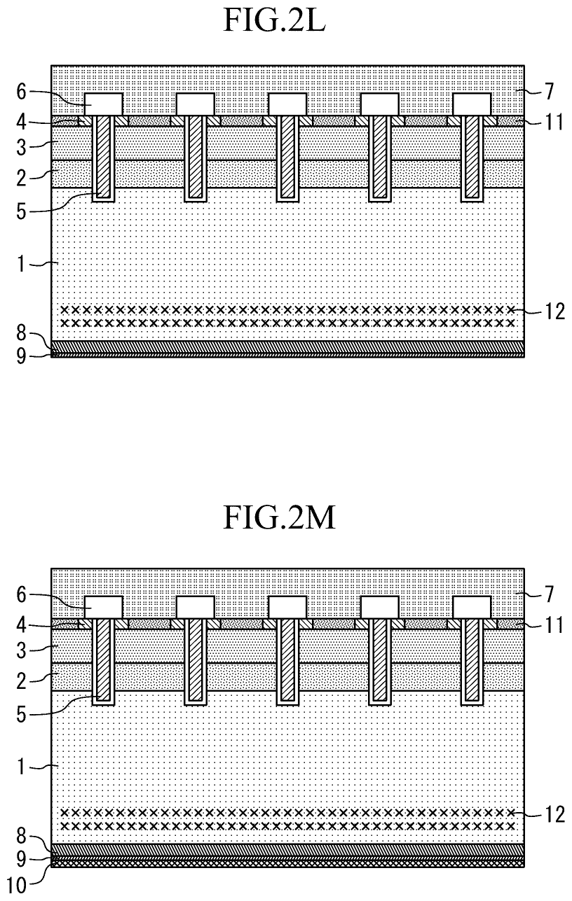

FIGS. 2A to 2M are diagrams describing a method for manufacturing the semiconductor device 100 according to the first embodiment. First, as shown in FIG. 2A, an n-type semiconductor substrate with the drift layer 1 formed therein is prepared. The semiconductor substrate has a specific resistance more than or equal to 20 Ω·cm and less than or equal to 100 Ω·cm, which is a typical specific resistance for an in-vehicle product, for example. Next, as shown in a plan view of FIG. 2B, a p-type termination region 33 necessary for holding the withstand voltage of the IGBT is formed by thermal treatment at high temperatures for a long time so as to surround a cell region 31 of the IGBT. Note that a gate wiring region 32 is provided between the cell region 31 and the termination region 33.

Next, as shown in FIGS. 2C and 2D, the CS layer 2 and the base layer 3 are selectively formed using the photolithography technology. In order to form the CS layer 2 under the base layer 3, it is effective to implant phosphorus at high energy in terms of mega-electron volt and to perform high-temperature driving after implantation of phosphorus. Next, as shown in FIG. 2E, the emitter layer 4 is selectively formed of phosphorus or arsenic.

Next, as shown in FIG. 2F, trenches are formed by dry etching, and a gate oxide film is formed by thermal oxidation or chemical vapor deposition (CVD). Moreover, polysilicon is embedded into the trenches by CVD. Thereafter, as shown in FIG. 2G, the contact layer 11 is formed. Note that the emitter layer 4 may be formed after the trenches are formed.

Next, as shown in FIG. 2H, tetraethoxysilane (TEOS), boron phosphorus (BP) TEOS, or the like to be the interlayer insulation film 6 is deposited, and then a contact pattern is selectively formed. Next, as shown in FIG. 2I, the emitter electrode 7 is formed of Al, AlSi, AlCu, Cu, or the like by sputtering or vapor deposition. A glass coat or polyimide is deposited on the emitter electrode 7 according to necessity.

Next, a rear surface wafer process is started. As shown in FIG. 2J, silicon positioned in the rear surface side is polished to make the wafer thinner. Thereafter, as shown in FIG. 2K, protons are implanted from the rear surface to form the crystal defect region 12. Thereafter, as shown in FIG. 2L, phosphorus and boron are ion-implanted from the rear surface so as to form the buffer layer 8 containing phosphorus and the collector layer 9 containing boron. The buffer layer 8 is formed by ion implantation at several hundred kilo-electron volts to several mega-electron volts, for example, so as to become deeper than the collector layer 9. Note that the order of implanting protons, phosphorus, and boron can be changed.

Thereafter, phosphorus and boron are activated by laser annealing or conventional annealing through use of a furnace. Thermal treatment is also performed for repairing crystal defects formed by proton implantation to a certain degree. The high resistance region 21 and the low resistance region 22 can be simultaneously formed by implantation of protons and thermal treatment as described above. Note that the order of thermal treatment by laser annealing and thermal treatment for repairing crystal defects can be changed.

Finally, as shown in FIG. 2M, the collector electrode 10 is formed. A plurality of laminated films of ASi, Ti, Ni, Au, Ag, and the like are preferably formed as the collector electrode 10 by sputtering or vapor deposition in consideration of contacts which form a highly ohmic contact with silicon, and solder joints.

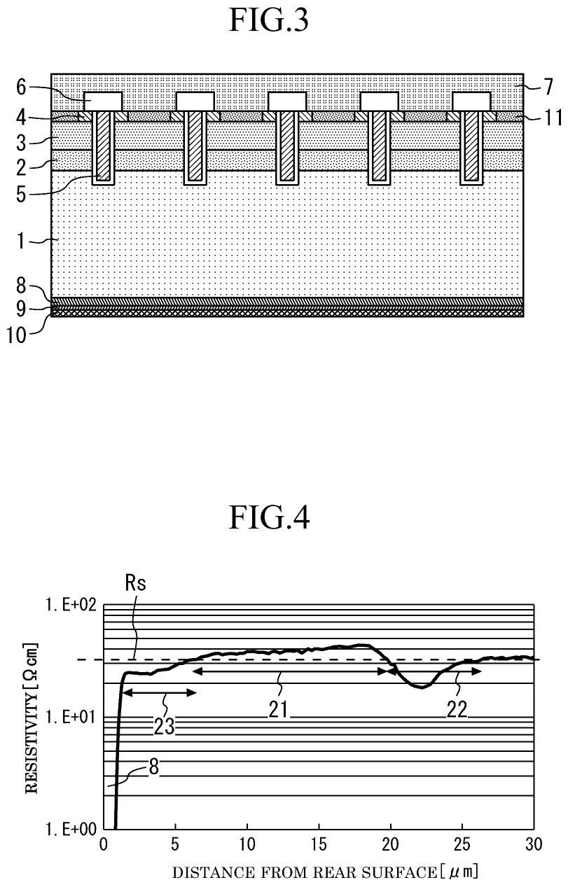

Next, the high resistance region 21 and the low resistance region 22 will be described in detail. FIG. 3 is a cross-sectional view of a semiconductor device according to a comparative example. The semiconductor device according to the comparative example is different from the semiconductor device 100 of the present embodiment in that the crystal defect region 12 is not provided. When a semiconductor device such as an IGBT as shown in FIG. 3 is brought into a short-circuit state due to a malfunction of a control circuit, or the like, a high voltage and a high current may be applied. In order to prevent the semiconductor device from breaking down on this occasion, semiconductor devices typically have a protection circuit. However, a time difference occurs until the protection circuit starts activating after the short-circuit state occurs. Therefore, semiconductor devices need to be designed so as not to break down for about several microseconds even in the short-circuit state.

Therefore, one of characteristics required of a semiconductor device is a short-circuit duration for which the semiconductor device withstands a short circuit without breaking down when in a short-circuit operation, and a lower limit value is set for the short-circuit duration. As the short-circuit duration is longer, reliability and safety of a system can be increased. In a semiconductor device having an excessive short-circuit duration, a wafer is made thin to reduce a margin of the short-circuit duration in some cases. This enables further improvement in performance.

Factors of breakdown due to a short circuit include an occurrence of a latch-up operation, disappearance of a pn junction of the IGBT because of heat generation and elevation in temperature of the semiconductor device, and the like. Therefore, in order to suppress breakdown due to a short circuit, it is effective to reduce carriers in the semiconductor device. The high resistance region has the function of causing carriers to vanish. However, when the high resistance region is formed in the principal surface side of the semiconductor substrate, reliability of the gate oxide film is affected. Therefore, the high resistance region is desirably provided in the principal surface side of the semiconductor substrate. Accordingly, holes from the rear surface of the semiconductor substrate can be caused to vanish, so that the short-circuit withstand capability can be improved.

However, when the resistance region has an excessively high resistance, a leakage current increases. Therefore, thermal runaway is likely to occur. The resistance region can be formed by implanting protons, helium, or the like. However, the resistance will be excessively high merely by implanting protons, helium, or the like. Thus, thermal treatment at low temperatures of about 300 to 400° C. is preferably performed to locally repair crystal defects in a region through which protons, helium, or the like pass.

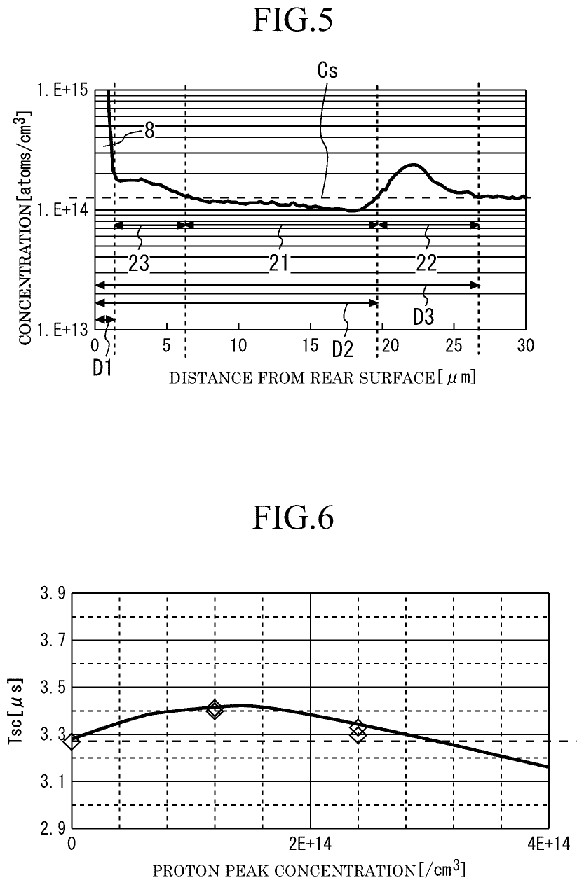

FIG. 4 is a diagram showing a relationship between distance from the rear surface of the semiconductor substrate and resistivity in the semiconductor device 100 according to the first embodiment. FIG. 5 is a diagram showing a relationship between distance from the rear surface of the semiconductor substrate and carrier concentration in the semiconductor device 100 according to the first embodiment. FIGS. 4 and 5 show the resistivity and the carrier concentration in the rear surface side of the semiconductor substrate examined for the semiconductor device 100 by the spreading resistance (SR) method. The resistivity can be acquired by the SR method of examining the concentration of a diffusion layer. FIG. 5 shows a result obtained by converting the acquired resistivity into the carrier concentration. FIG. 4 shows a substrate resistance Rs, that is, the resistance of the drift layer 1 by a broken line. FIG. 5 shows a substrate concentration Cs, that is, the carrier concentration of the drift layer 1 by a broken line. Note that the collector layer 9 is shallow and thus fails to be detected in the measurement results of FIGS. 4 and 5.

The high resistance region 21 corresponds to the crystal defect region 12. In the present embodiment, the high resistance region 21 is made wider than the low resistance region 22. That is, the high resistance region 21 is formed to be thicker than the low resistance region 22. The high resistance region 21 contains many crystal defects. Therefore, holes from the rear surface of the semiconductor substrate can be reduced significantly because of the thick high resistance region 21, so that excessive holes from the rear surface of the semiconductor substrate can be caused to vanish. Consequently, suppression of latch-up and heat generation of the semiconductor device 100 can be achieved, so that the short-circuit withstand capability can be improved.

The low resistance region 22 can slowly stop a depletion layer that spreads from the principal surface of the semiconductor substrate when holding the withstand voltage. Consequently, oscillation at turn-off can be suppressed by the low resistance region 22. Note that the low resistance region 22 functions as an n-type buffer and has the function of reducing holes, but is not more effective than the high resistance region 21. Therefore, a larger effect for improving the short-circuit withstand capability tends to be obtained by making the high resistance region 21 wider than the low resistance region 22. From the foregoing, the present embodiment can achieve both improvement of the short-circuit withstand capability and suppression of oscillation by providing the high resistance region 21 and the low resistance region 22 in the rear surface side of the semiconductor substrate and making the high resistance region 21 thicker than the low resistance region 22.

Efficiency of implanting holes from the rear surface can be lowered since the semiconductor device 100 possesses the buffer layer 8 containing phosphorus in the rear surface side of the semiconductor substrate. Consequently, the short-circuit withstand capability can further be improved.

The buffer layer 8 has a depth less than or equal to 2 μm, for example, from the rear surface of the semiconductor substrate. Specifically, a depth D1 to a position at which the carrier concentration of the buffer layer 8 is flattened beyond a position at which the carrier concentration is at the peak is less than or equal to 2 μm. The high resistance region 21 has a depth less than or equal to 20 μm, for example, from the rear surface of the semiconductor substrate. Specifically, a depth D2 to a position at which the carrier concentration reaches the substrate concentration Cs from below the substrate concentration Cs is less than or equal to 20 μm. The low resistance region 22 has a depth less than or equal to 30 μm, for example, from the rear surface of the semiconductor substrate. Specifically, a depth D3 to a position at which the carrier concentration of the low resistance region 22 is equivalent to the substrate concentration Cs beyond a position at which the carrier concentration is at the peak is less than or equal to 30 μm.

The high resistance region 21 and the low resistance region 22 contain protons as an impurity. As described above, the high resistance region 21 and the low resistance region 22 can be formed by implanting protons from the rear surface of the semiconductor substrate and performing low-temperature annealing. The high resistance region 21 is formed in the region through which protons pass, and the low resistance region 22 is formed in a region in which protons stop. When the amount of implanted protons is increased, the high resistance region 21 tends to have higher resistance, and the low resistance region 22 tends to have lower resistance.

The carrier concentration of the high resistance region 21 is preferably more than or equal to 5×10¹³/cm³. As described above, the short-circuit withstand capability can be improved by causing holes from the rear surface to vanish to a certain degree. However, when the concentration of the high resistance region 21 is excessively lowered, that is, when the resistance is excessively high, a carrier life time in the high resistance region decreases, which might increase the leakage current and reduce the short-circuit withstand capability. The present embodiment can prevent holes from the rear surface from vanishing when in a short-circuit operation by increasing the concentration of the high resistance region 21. Consequently, the short-circuit withstand capability is expected to be improved.

Next, the low concentration buffer region 23 will be described. The low concentration buffer region 23 is formed between the high resistance region 21 and the buffer layer 8 containing phosphorus. The low concentration buffer region 23 is higher in carrier concentration than the drift layer 1 and lower in carrier concentration than the buffer layer 8. In order to activate phosphorus in the buffer layer 8 and boron in the collector layer 9, laser annealing is performed toward the rear surface of the semiconductor substrate to elevate the temperature of only the outermost surface of the rear surface. Because heat on this occasion somewhat propagates toward the front surface of the semiconductor substrate, protons contained in the rear surface side of the high resistance region 21 partially become donors, so that a transition region is formed. This transition region serves as the low concentration buffer region 23. However, when excessive heat propagates toward the front surface of the semiconductor substrate, an aluminum electrode on the front surface is melted.

That is, the low concentration buffer region 23 can also be regarded as a second low resistance region containing protons as an impurity and being lower in resistance than the drift layer 1. The low concentration buffer region 23 ranges from the position of the depth D1 in FIG. 5 to the position at which the carrier concentration becomes the substrate concentration Cs. By virtue of the low concentration buffer region 23, holes from the collector on the rear surface can be prevented from abruptly vanishing in the high resistance region when in a turn-on operation. This is expected to contribute to stabilization of operation when a short circuit occurs.

FIG. 6 is a diagram showing a relationship between proton peak concentration and short-circuit duration. Semiconductor devices are produced experimentally with amounts of implanted protons distributed, and the proton peak concentration examined by the SR method is indicated on the horizontal axis of FIG. 6. The peak concentration of the low resistance region 22 in FIG. 5 corresponds to the proton peak concentration in FIG. 6. According to FIG. 6, the short-circuit duration is longer than in a case in which the peak concentration is zero, that is, a case in which there is no proton implantation, by making the peak concentration of protons less than or equal to 3.0×10¹⁴/cm³. That is, it is revealed that carriers within the semiconductor device 100 can be caused to vanish appropriately by making the peak concentration of protons in the low resistance region 22 less than or equal to 3.0×10¹⁴/cm³, so that the short-circuit withstand capability can be improved.

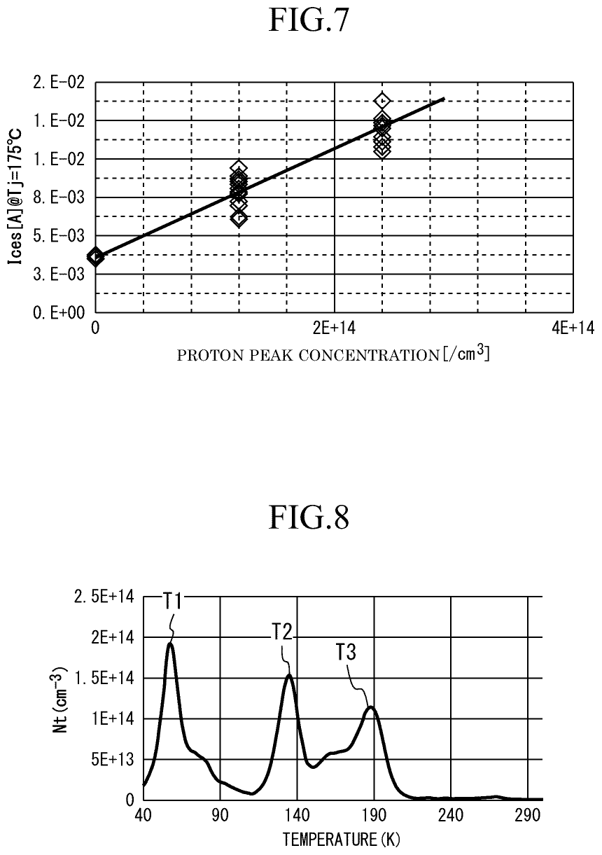

On the other hand, when the proton peak concentration is made more than 3.0×10¹⁴/cm³, the short-circuit withstand capability decreases as compared with the case in which the peak concentration is zero. FIG. 7 is a diagram showing a relationship between proton peak concentration and leakage current. As the proton peak concentration is larger, the leakage current increases. This is because when the amount of implanted protons is increased, crystal defects increase, and the leakage current increases. That is, it is considered that the influence by the leakage current increases due to the effect of carrier vanishment due to the crystal defects, leading to susceptibility to thermal runaway of the semiconductor device, so that the short-circuit duration decreases.

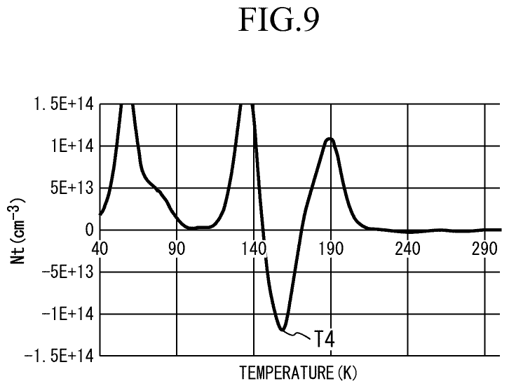

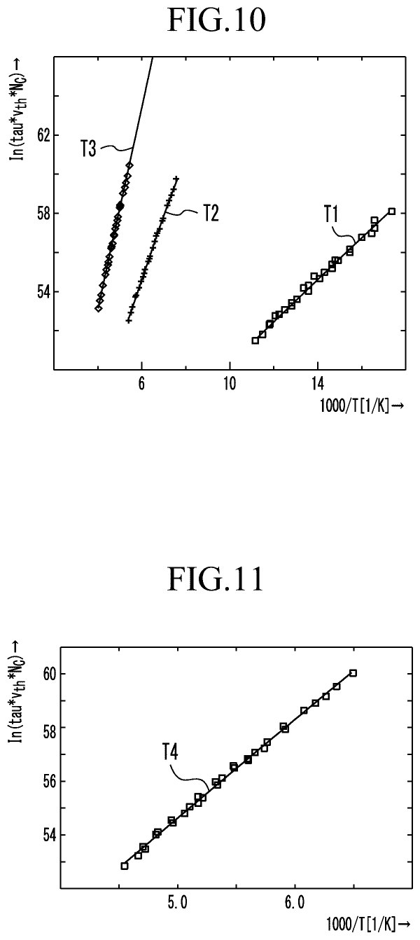

Next, an energy level of crystal defects formed of protons in the rear surface side of the semiconductor substrate of the present embodiment is examined. Specifically, protons are implanted in the front surface of the semiconductor substrate at a dose of 2.5×10¹²/cm², and deep level transient spectroscopy (DLTS) is measured. Note that the peak concentration is about 5×10¹⁴/cm³. FIG. 8 is a diagram showing a DLTS spectrum of electron traps obtained by proton implantation in the present embodiment. FIG. 9 is a diagram showing a DLTS spectrum of hole traps obtained by proton implantation in the present embodiment. FIG. 10 is a diagram showing an Arrhenius plot of electron traps obtained by proton implantation in the present embodiment. FIG. 11 is a diagram showing an Arrhenius plot of hole traps obtained by proton implantation in the present embodiment.

Electron traps at Ec−0.1±0.05 eV, Ec−0.28±0.05 eV, and Ec−0.44±0.05 eV and hole traps at Ev+0.33±0.05 eV are formed in the rear surface side of the drift layer 1. The respective traps are indicated as T1 to T4 in FIGS. 8 to 11. At such energy levels of electrons and holes, the short-circuit withstand capability can be improved.

A trap concentration effective for improving the short-circuit duration is estimated by conversion from the peak concentration of the traps. The trap concentration of the rear surface side of the drift layer 1 is preferably less than or equal to 9.3×10¹³/cm³ or more than or equal to 5.4×10¹³/cm³. That is, 9.3×10¹³/cm³ is the maximum value of the trap concentration of electrons and holes at which the short-circuit withstand capability can be improved. In addition, 5.4×10¹³/cm³ is the minimum value of the trap concentration of electrons and holes at which the short-circuit withstand capability can be improved.

In the present embodiment, the example of forming the high resistance region 21 and the low resistance region 22 by proton implantation has been described. The high resistance region 21 and the low resistance region 22 may be formed by implanting helium, which hardly becomes donor, at a large amount of implantation rather than protons.

In addition, the semiconductor substrate may be formed of silicon, or may be formed of wide bandgap semiconductor. The wide bandgap semiconductor is silicon carbide, a gallium nitride-based material, or diamond.

Meanwhile, technical features explained in each embodiment may be appropriately combined to use.

Hereinafter, various aspects of the present disclosure will be collectively described as appendixes.

### APPENDIX 1

A semiconductor device comprising:
a semiconductor substrate having a principal surface and a rear surface opposite to the principal surface;
a main electrode formed on the principal surface of the semiconductor substrate;
a gate electrode formed in the principal surface side of the semiconductor substrate; and
a rear surface electrode formed on the rear surface of the semiconductor substrate, wherein
the semiconductor substrate includes
   a drift layer,
   a low resistance region formed in the rear surface side of the drift layer and being lower in resistance than the drift layer,
   a high resistance region formed in the rear surface side of the low resistance region and being higher in resistance than the drift layer, and
   a buffer layer formed in the rear surface side of the high resistance region and containing phosphorus, and
the high resistance region is thicker than the low resistance region.

### APPENDIX 2

The semiconductor device according to appendix 1, wherein the high resistance region and the low resistance region contain protons.

### APPENDIX 3

The semiconductor device according to appendix 2, wherein the low resistance region has a peak concentration of the protons less than or equal to 3.0×10¹⁴/cm³.

### APPENDIX 4

The semiconductor device according to appendix 2 or 3, wherein an electron trap at Ec−0.1±0.05 eV, Ec−0.28±0.05 eV, and Ec−0.44±0.05 eV and a hole trap at Ev+0.33±0.05 eV are formed in the rear surface side of the drift layer.

### APPENDIX 5

The semiconductor device according to any one of appendixes 2 to 4, wherein a trap concentration in the rear surface side of the drift layer is less than or equal to 9.3×10¹³/cm³.

### APPENDIX 6

The semiconductor device according to any one of appendixes 2 to 5, wherein a trap concentration in the rear surface side of the drift layer is more than or equal to 5.4×10¹³/cm³.

### APPENDIX 7

The semiconductor device according to any one of appendixes 1 to 6, wherein
the buffer layer has a depth less than or equal to 2 μm from the rear surface,
the high resistance region has a depth less than or equal to 20 μm from the rear surface, and
the low resistance region has a depth less than or equal to 30 μm from the rear surface.

### APPENDIX 8

The semiconductor device according to any one of appendixes 1 to 7, further comprising a low concentration buffer region formed between the high resistance region and the buffer layer and being higher in carrier concentration than the drift layer.

### APPENDIX 9

The semiconductor device according to any one of appendixes 1 to 8, wherein the semiconductor substrate is made with a wide band gap semiconductor.

### APPENDIX 10

The semiconductor device according to appendix 9, wherein the wide band gap semiconductor is silicon carbide, gallium-nitride-based material or diamond.

The semiconductor device according to the present disclosure enables excessive holes from the rear surface of the semiconductor substrate to vanish by making the high resistance region thicker than the low resistance region, so that the short-circuit withstand capability can be improved.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-093159, filed on Jun. 7, 2024 including specification, claims, drawings and summary, on which the Convention priority of the present application is based, are incorporated herein by reference in its entirety.

1. A semiconductor device comprising:
a semiconductor substrate having a principal surface and a rear surface opposite to the principal surface;
a main electrode formed on the principal surface of the semiconductor substrate;
a gate electrode formed in the principal surface side of the semiconductor substrate; and
a rear surface electrode formed on the rear surface of the semiconductor substrate, wherein
the semiconductor substrate includes
a drift layer,
a low resistance region formed in the rear surface side of the drift layer and being lower in resistance than the drift layer,
a high resistance region formed in the rear surface side of the low resistance region and being higher in resistance than the drift layer, and
a buffer layer formed in the rear surface side of the high resistance region and containing phosphorus, and
the high resistance region is thicker than the low resistance region.

2. The semiconductor device according to claim 1, wherein the high resistance region and the low resistance region contain protons.

3. The semiconductor device according to claim 2, wherein the low resistance region has a peak concentration of the protons less than or equal to 3.0×10¹⁴/cm³.

4. The semiconductor device according to claim 2, wherein an electron trap at Ec−0.1±0.05 eV, Ec−0.28±0.05 eV, and Ec−0.44±0.05 eV and a hole trap at Ev+0.33±0.05 eV are formed in the rear surface side of the drift layer.

5. The semiconductor device according to claim 2 wherein a trap concentration in the rear surface side of the drift layer is less than or equal to 9.3×10¹³/cm³.

6. The semiconductor device according to claim 2, wherein a trap concentration in the rear surface side of the drift layer is more than or equal to 5.4×10¹³/cm³.

7. The semiconductor device according to claim 1 wherein
the buffer layer has a depth less than or equal to 2 μm from the rear surface,
the high resistance region has a depth less than or equal to 20 μm from the rear surface, and
the low resistance region has a depth less than or equal to 30 μm from the rear surface.

8. The semiconductor device according to claim 1, further comprising a low concentration buffer region formed between the high resistance region and the buffer layer and being higher in carrier concentration than the drift layer.

9. The semiconductor device according to claim 1, wherein the semiconductor substrate is made with a wide band gap semiconductor.

10. The semiconductor device according to claim 9, wherein the wide band gap semiconductor is silicon carbide, gallium-nitride-based material or diamond.
